(19) United States
(12) Patent Application Publication
(10) Pub. No.: US 2021/0173003 A1
(43) Pub. Date: Jun. 10, 2021

(54) PROBE APPARATUS

(71) Applicant: TECAT TECHNOLOGIES (SUZHOU) LIMITED, Suzhou Industrial Park (CN)

(72) Inventors: CHANG-MING LIN, SAN JOSE, CA (US); Choon Leong LOU, Singapore (SG)

(21) Appl. No.: 16/730,684

(22) Filed: Dec. 30, 2019

(30) Foreign Application Priority Data
Dec. 6, 2019 (CN) 201911241931.X

(51) Int. Cl. G01R 31/28; G01R 1/067; G01R 1/04

(52) U.S. Cl. CPC G01R 31/2886; G01R 1/06761; G01R 1/0491; G01R 1/0675

(57) ABSTRACT

The present disclosure provides a probe apparatus, including a circuit board, a flexible interconnect substrate, at least one probe, and a supporting element. The circuit board includes tester contacts. The flexible interconnect substrate has a first surface and an opposing second surface. The flexible interconnect substrate is electrically coupled to the circuit board. The probe is disposed in the first surface of the flexible interconnect substrate. The probe is electrically coupled to the flexible interconnect substrate, and the probe is configured to electrically contact a device under test. The supporting element is adhered to the second surface of the flexible interconnect substrate. The supporting element is disposed between the flexible interconnect substrate and the circuit board.

### TECHNICAL FIELD

The present disclosure relates to a probe apparatus with a flexible substrate and a supporting element.

### DISCUSSION OF THE BACKGROUND

The semiconductor industry has experienced continued rapid growth due to improvements with integration density. In general, it is necessary to test the electrical characteristics of integrated circuit devices on the wafer level to check whether the integrated circuit device satisfies the product specification. Integrated circuit devices with electrical characteristic satisfying the specification will be selected for the subsequent packaging process, while other devices will be discarded to avoid additional packaging cost. Often another electrical property test will be performed on the integrated circuit device after the packaging process is completed to screen out the below standard devices to increase the product yield. It is therefore crucial that the probe apparatus performing the tests be robust and adaptable without potentially damaging the device under test.

This Discussion of the Background section is provided for background information only. The statements in this Discussion of the Background are not an admission that the subject matter disclosed in this section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides a probe apparatus, including a circuit board, a flexible interconnect substrate, at least one probe, and a supporting element. The circuit board includes tester contacts. The flexible interconnect substrate has a first surface and an opposing second surface, wherein the flexible interconnect substrate is electrically coupled to the circuit board. The probe is disposed in the first surface of the flexible interconnect substrate, wherein the probe is electrically coupled to the flexible interconnect substrate, and the probe is configured to electrically contact a device under test. The supporting element is adhered to the second surface of the flexible interconnect substrate, wherein the supporting element is disposed between the flexible interconnect substrate and the circuit board.

In some embodiments, the supporting element is an anisotropic elastomer comprising a homogeneous or non-homogeneous texture.

In some embodiments, the supporting element is an anisotropic elastomer comprising a heterogeneous texture.

In some embodiments, the probe comprises a symmetrical cross-section.

In some embodiments, the probe comprises an asymmetrical cross-section.

In some embodiments, the probe comprises a single contact mark, a plurality of contact marks, or a contact mark area.

In some embodiments, the flexible interconnect substrate comprises a plurality of ground layers, a plurality of signal layers, and a plurality of dielectric layers.

Another aspect of the present disclosure provides a probe apparatus, including a circuit board, a flexible interconnect substrate, at least one probe, and a supporting element. The circuit board includes tester contacts. The flexible interconnect substrate has a first surface and an opposing second surface, wherein the flexible interconnect substrate is electrically coupled to the circuit board. The probe is disposed in the first surface of the flexible interconnect substrate, wherein the probe is electrically coupled to the flexible interconnect substrate, and the probe is configured to electrically contact a device under test. The supporting element is adhered to a region of the circuit board facing the second surface of the flexible interconnect substrate, wherein the supporting element is disposed between the flexible interconnect substrate and the circuit board.

In some embodiments, a metal film is disposed between the supporting element and the circuit board.

In some embodiments, the supporting element is an anisotropic elastomer comprising a homogeneous texture, a non-homogeneous texture, or a heterogeneous texture.

In some embodiments, the probe comprises a symmetrical cross-section.

In some embodiments, the probe comprises an asymmetrical cross-section.

In some embodiments, the probe comprises a single contact mark, a plurality of contact marks, or a contact mark area.

In some embodiments, the flexible interconnect substrate comprises a plurality of ground layers, a plurality of signal layers, and a plurality of dielectric layers.

Another aspect of the present disclosure provides a probe apparatus, including a circuit board, a flexible interconnect substrate, at least one probe, and a supporting element. The circuit board includes tester contacts. The flexible interconnect substrate has a first surface and an opposing second surface, wherein the flexible interconnect substrate is electrically coupled to the circuit board. The probe is disposed in the first surface of the flexible interconnect substrate, wherein the probe is electrically coupled to the flexible interconnect substrate, and the probe is configured to electrically contact a device under test. The supporting element is adhered to a region of a metal block facing the second surface of the flexible interconnect substrate, wherein the metal block is attached to the circuit board, and the supporting element is disposed between the flexible interconnect substrate and the circuit board.

In some embodiments, the supporting element is an anisotropic elastomer comprising a homogeneous texture, a non-homogeneous texture or a heterogeneous texture.

In some embodiments, the probe comprises a symmetrical cross-section.

In some embodiments, the probe comprises an asymmetrical cross-section.

In some embodiments, the probe comprises a single contact mark, a plurality of contact marks, or a contact mark area.

In some embodiments, the flexible interconnect substrate comprises a plurality of ground layers, a plurality of signal layers, and a plurality of dielectric layers.

Accordingly, due to the supporting elements in the probe apparatuses of the present disclosure, potential contact damage with the device under test can be minimized or eliminated. Moreover, the supporting elements serve as mechanical cushions to enhance the uniformity of the contact force of the probes across the whole device under test. On the other hand, device integration in the flexible interconnect substrates of the probe apparatuses enable high density interconnect (HDI) electrical routing layouts capable of performing specialized functions.

The foregoing has outlined rather broadly the features and technical advantages of the present disclosure in order that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

A more complete understanding of the present disclosure may be derived by referring to the detailed description and claims when considered in connection with the Figures, where like reference numbers refer to similar elements throughout the Figures, and:

FIG. 1 is a schematic diagram of a probe apparatus according to some embodiments of the present disclosure;

FIG. 2 is a side cross-sectional view of a flexible interconnect substrate according to some embodiments of the present disclosure;

FIG. 3A is a top view of a probe according to some embodiments of the present disclosure;

FIG. 3B is a side cross-sectional view of a probe according to some embodiments of the present disclosure;

FIG. 3C is a perspective view of a probe according to some embodiments of the present disclosure;

FIG. 4 is a schematic diagram of a probe apparatus according to some embodiments of the present disclosure;

FIG. 5 is a side cross-sectional view of a flexible interconnect substrate according to some embodiments of the present disclosure;

FIG. 6A is a top view of a probe according to some embodiments of the present disclosure;

FIG. 6B is a side cross-sectional view of a probe according to some embodiments of the present disclosure;

FIG. 6C is a perspective view of a probe according to some embodiments of the present disclosure;

FIG. 7 is a schematic diagram of a probe apparatus according to some embodiments of the present disclosure;

FIG. 8 is a side cross-sectional view of a flexible interconnect substrate according to some embodiments of the present disclosure;

FIG. 9A is a top view of a probe according to some embodiments of the present disclosure;

FIG. 9B is a side cross-sectional view of a probe according to some embodiments of the present disclosure; and

FIG. 9C is a perspective view of a probe according to some embodiments of the present disclosure.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that, although the terms first, second, third, etc. may be used herein to describe various elements, components, regions, layers or sections, these elements, components, regions, layers or sections are not limited by these terms. Rather, these terms are merely used to distinguish one element, component, region, layer or section from another element, component, region, layer or section. Thus, a first element, component, region, layer or section discussed below could be termed a second element, component, region, layer or section without departing from the teachings of the present inventive concept.

The terminology used herein is for the purpose of describing particular example embodiments only and is not intended to be limited to the present inventive concept. As used herein, the singular forms “a,” “an” and “the” are intended to include the plural forms as well, unless the context clearly indicates otherwise. It shall be further understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

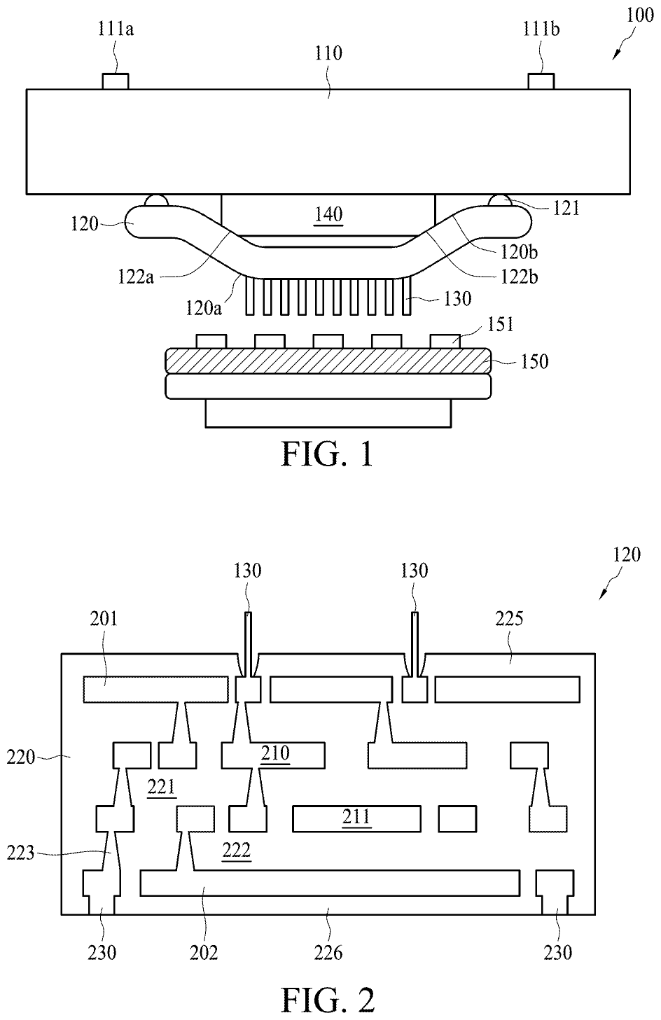

FIG. 1 is a schematic diagram of a probe apparatus 100 according to some embodiments of the present disclosure. With reference to FIG. 1, the probe apparatus 100 includes a circuit board 110, a flexible interconnect substrate 120, at least one probe 130, and a supporting element 140. In some embodiments, the circuit board 110 includes contact pads 111a and 111b for making contact with a tester equipment (not shown), for example. The contact pads 111a and 111b may make contact with pogo-style pins of the tester equipment, for instance. The circuit board 110 may also serve as a carrier board for the flexible interconnect substrate 120. In some embodiments, the flexible interconnect substrate 120 has a first surface 120a and an opposing second surface 120b, and the flexible interconnect substrate 120 is electrically coupled to the circuit board 110 through the electrical connections 121.

In some embodiments, the electrical connections 121 serve to electrically and mechanically connect the circuit board 110 to the flexible interconnect substrate 120. The electrical connections 121 may include metal bumps formed with copper (Cu), gold (Au), silver (Ag), nickel (Ni), solder (Pb/Sn), bronze, brass, Paliney 6 alloy, or other suitable materials according to an electrolytic plating method, a reflow solder method, a direct inter-metal bonding method, a deposition method, or other suitable methods. In some embodiments, the electrical connections 121 may include stud bumps that are formed with gold (Au) or other suitable materials according to a wire bonding method. However, the electrical connections 121 are not limited to these types of structures. In some embodiments, when it is possible to obtain a desired electric connection by another method, the electrical connections 121 need not exist. In some embodiments, connection mediums other than metal bumps or stud bumps may be provided.

In some embodiments, the probe 130 is disposed in the first surface 120a of the flexible interconnect substrate 120. The probe 130 is electrically coupled to the flexible interconnect substrate 120, and the probe 130 is configured to electrically contact pads 151 of a device 150 under test. In some embodiments, the supporting element 140 is adhered to the second surface 120b of the flexible interconnect substrate 120, and the supporting element 140 is disposed between the flexible interconnect substrate 120 and the circuit board 110. In some embodiments, the supporting element 140 may be fixed to the flexible interconnect substrate 120 at regions 122a and 122b by an epoxy resin based adhering agent or other suitable adhesives. The supporting element 140 may be fixed to the flexible interconnect substrate 120 at regions 122a and 122b prior to the formation of the electrical connections 121 between the flexible interconnect substrate 120 and the circuit board 110.

In some embodiments, the supporting element 140 may be an anisotropic elastomer that may serve as a mechanical cushion to enhance the uniformity of a contact force of the probe 130 across the whole device 150 under test. The anisotropic elastomer material of the supporting element 140 may be made to have a homogeneous texture or a non-homogeneous texture, and/or homogeneous or non-homogeneous ingredients. In some embodiments, the anisotropic elastomer material of the supporting element 140 may be made to have a heterogeneous texture and/or heterogeneous ingredients. Accordingly, this may enable the supporting element 140 to be more dexterous while probing the device 150 under test, thereby minimizing or eliminating a potential contact damage to the device 150 under test. A thickness of the supporting element 140 may range from 0.1 mm to 5 mm, although the thickness of the supporting element 140 may be 0.3 mm to 1 mm, 0.4 mm to 1 mm, or 0.4 mm to 0.6 mm depending on particular applications of the probe apparatus 100 according to some embodiments of the present disclosure.

FIG. 2 is a side cross-sectional view of the flexible interconnect substrate 120 according to some embodiments of the present disclosure. With reference to FIG. 2, the flexible interconnect substrate 120 includes a plurality of ground layers 201 and 202, a plurality of signal layers 210 and 211, a plurality of dielectric layers 220, 221, and 222, a plurality of vias 223, a plurality of passivation layers 225 and 226, and metal pads 230. In some embodiments, the flexible interconnect substrate 120 may be a multi-layer membrane-like substrate. As shown in the illustrative example of FIG. 2, the flexible interconnect substrate 120 may include a plurality of metal layers with polymer dielectric layers in between. In the flexible interconnect substrate 120 of FIG. 2, the ground layers 201 and 202 form external layers which may be in a form of solid metal plane or mesh-net like metal networks. The signal layers 210 and 211 are metal layers formed in between the ground layers 201 and 202. The metal vias 223 interconnect the signal layers 210 and 211 by vertically penetrating through the polymer dielectric layers 220, 221, and 222. In some embodiments, the probe 130 may be fabricated on the ground layer 201 by a micro-electro-mechanical system (MEMS) process, an electrolytic plating process, a thin film process, or other suitable processing methods. The probe 130 may be fabricated on the ground layer 201 at predetermined locations (or coordinates) which are mirror image counterparts of the centers of the pads 151 on the device 150 to be tested (e.g. integrated circuit chip). In some embodiments, the metal pads 230 and/or metal bumps may be optionally erected on the ground layer 202 at predetermined solder joint spots by a standard soldering process, so as to enhance a reliable connection to the circuit board 110. The metal bump structure may form the electrical connections 121 and may also be erected by an electrolytic plating process.

In some embodiments, a thickness of the metal layers of the flexible interconnect substrate 120 may range from 1 μm to more than 20 μm, 3 μm to 10 μm, or 3 μm to 8 μm depending on the particular applications of the probing apparatus 100. A surface roughness of the metal layers may range from below 1 Å to 200 Å, below 1 Å to 100 Å, or 1 Å to 25 Å depending on the particular applications. In some embodiments, a line width/gap of the flexible interconnect substrate 120 has a range of 2 μm to 150 μm, 5 μm to 75 μm, 5 μm to 50 μm, or 5 μm to 35 μm depending on the particular applications of the probing apparatus 100. In some embodiments, the flexible interconnect substrate 120 may be fabricated by a thin film build-up process, a fine pitch printed circuit board (PCB) process, a combination of thin film and fine pitch PCB process, or a fine pitch flexible circuit board process.

In some embodiments, passive components, such as resistors, capacitors, or inductors may be integrated into the traces of the signal layers 210 and 211 of the flexible interconnect substrate 120 by a thin film process to perform specially designed functions such as electrical noise filtering, signal pull-up or pull-down, or other functions according to embodiments of the present disclosure. This thin film passive device integration further enables a high-density interconnect (HDI) flexible substrate of electrical routing layouts capable of performing specialized functions.

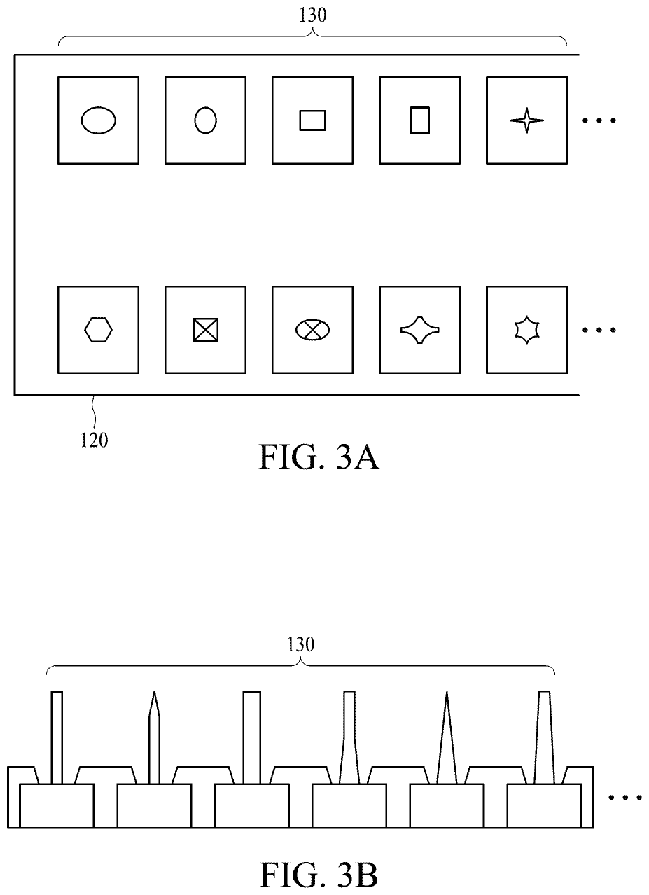

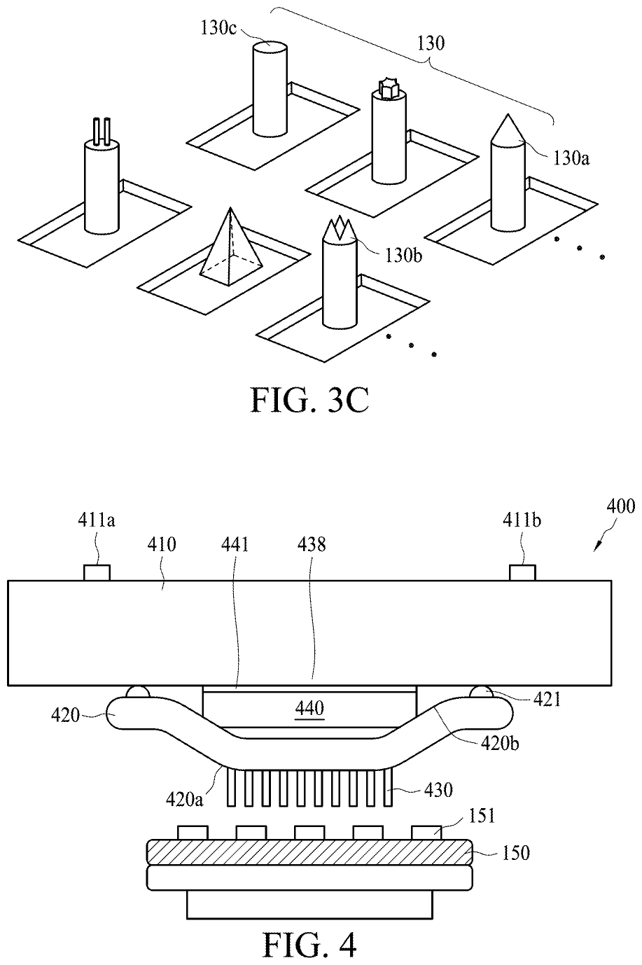

FIG. 3A is a top view of the probe 130, FIG. 3B is a side cross-sectional view of the probe 130, and FIG. 3C is a perspective view of the probe 130 according to some embodiments of the present disclosure. With reference to FIG. 2 and FIG. 3A to FIG. 3C, in some embodiments, the probe 130 is presented in a form of a metal post. The probe 130 may be formed to have a simple or complex geometrical shape, a symmetrical or asymmetrical cross-section as shown in FIG. 3A and FIG. 3B, and to have a single contact mark 130a, a plurality of contact marks 130b, or a contact mark area 130c, as shown in FIG. 3C. As seen in the illustrative example of FIG. 3A, the top-view shape of the probe 130 may vary from a circle, an oval, or to other symmetrical shapes or other irregular shapes. As seen in the illustrative example of FIG. 3B, the cross-section of the probe 130 may be rectangular, trapezoidal, square, triangular, or other symmetrical or asymmetrical cross-sections. It should be noted that, the probes 130 presented in FIG. 3A to FIG. 3C serve merely as illustrative examples of the shapes, cross-sections, and contact marks the probe 130 may have. The probe apparatus 100 may have probes 130 of different shapes, cross-sections, and contact marks compared to those presented in FIG. 3A to FIG. 3C. In another example, the probes 130 may have uniform shapes, cross-sections, and contact marks, or a mixture thereof according to some embodiments of the present disclosure. In some embodiments, a diameter of the probe 130 may vary from 1 μm to more than 30 μm, 1 μm to 10 μm, or 2 μm to 8 μm depending on the particular applications of the probing apparatus 100. In some embodiments, an inter-probe pitch may range from less than 30 μm to more than 100 μm, 35 μm to 75 μm, or 40 μm to 60 μm depending on the particular applications of the probing apparatus 100.

In some embodiments, the probes 130 of the probe apparatus 100 may be MEMS probes precisely positioned and uniformly made by a thin film process to have a pitch of 50 μm or less and compatible with semiconductor integrated circuit (IC) chips. If needed by particular applications, the probes 130 may be enhanced by plating or thermal tempering or other alternative methods, so as to easily surpass one million touch-downs under standard IC testing operation at room and elevated temperatures as well as under cycling of current or voltage, or functional testing in air or other types of atmospheres. A probe pitch of the probe 130 may be defined by a thin film process to match the needs of particular applications over a wide range of dimensions. For instance, the probe pitch may be as large as 1000 μm for semiconductor package or substrate testing, or smaller than 50 μm for fine pitch IC silicon wafer or wafer scale package testing. In some embodiments, a physical height of the probe 130 may range from less than 10 μm to more than 100 μm, depending on the particular applications of the probe apparatus 100.

In some embodiments, the probe 130 may be made of a simple and/or complex conductive material system with acceptable robustness and surface toughness. High conductivity metals and metal alloys may be used to manufacture the probe 130. In some embodiments, the probe 130 may be made of a single metal system, such as copper (Cu), silver (Ag), other suitable metallic equivalents, or an alloy system, such as bronze or Paliney 6 alloy or the like. In some embodiments, a grinding resistance of the probe 130 may be further improved by coating the probe 130 with a hard film, such as a nickel (Ni) film or the like. Other conductive material systems may be used for the probe 130, such as highly conductive oxides, polymers, composites, or other unforeseen disruptive conductive materials to be developed in future. In some embodiments, the probe 130 may be custom-made to meet demanding requirements of particular applications, such as corrosion resistance, abrasion resistance, chemical inertness, or other unique requirements. In some embodiments, the width or the diameter of the probe 130 may be made to gradually expand along a longitudinal axis of the probe 130, from the tip to the base of the probe 130, in order to enhance the position anchoring of the probe 130. In some embodiments, the probe 130 may be fabricated by a thin film MEMS process, a thin film deposition method, an electrolytic plating (or bumping) method, a stud bonding assembly method, or by a combination of any two or more of the aforementioned methods or yet to be invented new processing techniques.

It should be noted that, in some embodiments of the present disclosure, the supporting element of the probe apparatus may be configured differently than in the probe apparatus 100. FIG. 4 is a schematic diagram of a probe apparatus 400 according to some embodiments of the present disclosure. With reference to FIG. 4, the probe apparatus 400 includes a circuit board 410, a flexible interconnect substrate 420, at least one probe 430, and a supporting element 440. Compared to the probe apparatus 100 of FIG. 1, the supporting element 440 is mechanically supported by a planarized region 438 on the circuit board 410. In some embodiments, a metal film 441 is disposed between the supporting element 440 and the circuit board 410, and the region 438 may be coated by the metal film 441. In some embodiments, the circuit board 410 includes contact pads 411a and 411b for making contact with a tester equipment (not shown), for example. The contact pads 411a and 411b may make contact with pogo-style pins of the tester equipment, for instance. The circuit board 410 may also serve as a carrier board for the flexible interconnect substrate 420. In some embodiments, the flexible interconnect substrate 420 has a first surface 420a and an opposing second surface 420b, and the flexible interconnect substrate 420 is electrically coupled to the circuit board 410 through the electrical connections 421.

In some embodiments, the electrical connections 421 serve to electrically and mechanically connect the circuit board 410 to the flexible interconnect substrate 420. The electrical connections 421 may include metal bumps formed with copper (Cu), gold (Au), silver (Ag), nickel (Ni), solder (Pb/Sn), bronze, brass, Paliney 6 alloy, or other suitable materials according to an electrolytic plating method, a reflow solder method, a direct inter-metal bonding method, a deposition method, or other suitable methods. In some embodiments, the electrical connections 421 may include stud bumps that are formed with gold (Au) or other suitable materials according to a wire bonding method. However, the electrical connections 421 are not limited to these types of structures. In some embodiments, when it is possible to obtain a desired electric connection by another method, the electrical connections 421 need not exist. In some embodiments, connection mediums other than metal bumps or stud bumps may be provided.

In some embodiments, the probe 430 is disposed in the first surface 420a of the flexible interconnect substrate 420. The probe 430 is electrically coupled to the flexible interconnect substrate 420, and the probe 430 is configured to electrically contact pads 151 of a device 150 under test. In some embodiments, the supporting element 440 is adhered to the region 438 of the circuit board 410 facing the second surface 420b of the flexible interconnect substrate 420, by using an epoxy resin based adhering agent or other suitable adhesives, for example. The supporting element 440 is disposed between the flexible interconnect substrate 420 and the circuit board 410. In some embodiments, the metal film 441 is disposed between the supporting element 440 and the circuit board 410. The metal film 441 may be a metal thin film such as copper (Cu) foil, silver (Ag) foil, gold (Au) foil, or other electrolytic plating metal films or the like. It should be noted that, in some embodiments, the supporting element 440 may also be adhered to both the circuit board 410 and the flexible interconnect substrate 420 by an epoxy resin based adhering agent or other suitable adhesives, for example.

In some embodiments, the supporting element 440 may be an anisotropic elastomer that may serve as a mechanical cushion to enhance the uniformity of a contact force of the probe 430 across the whole device 150 under test. The anisotropic elastomer material of the supporting element 440 may be made to have a homogeneous texture or a non-homogeneous texture, and/or homogeneous or non-homogeneous ingredients. In some embodiments, the anisotropic elastomer material of the supporting element 440 may be made to have a heterogeneous texture and/or heterogeneous ingredients. Accordingly, this may enable the supporting element 440 to be more dexterous while probing the device 150 under test, thereby minimizing or eliminating a potential contact damage to the device 150 under test. A thickness of the supporting element 440 may range from 0.1 mm to 15 mm, although the thickness of the supporting element 440 may be 0.3 mm to 1 mm, 0.4 mm to 1 mm, or 0.4 mm to 0.6 mm depending on particular applications of the probe apparatus 400 according to some embodiments of the present disclosure.

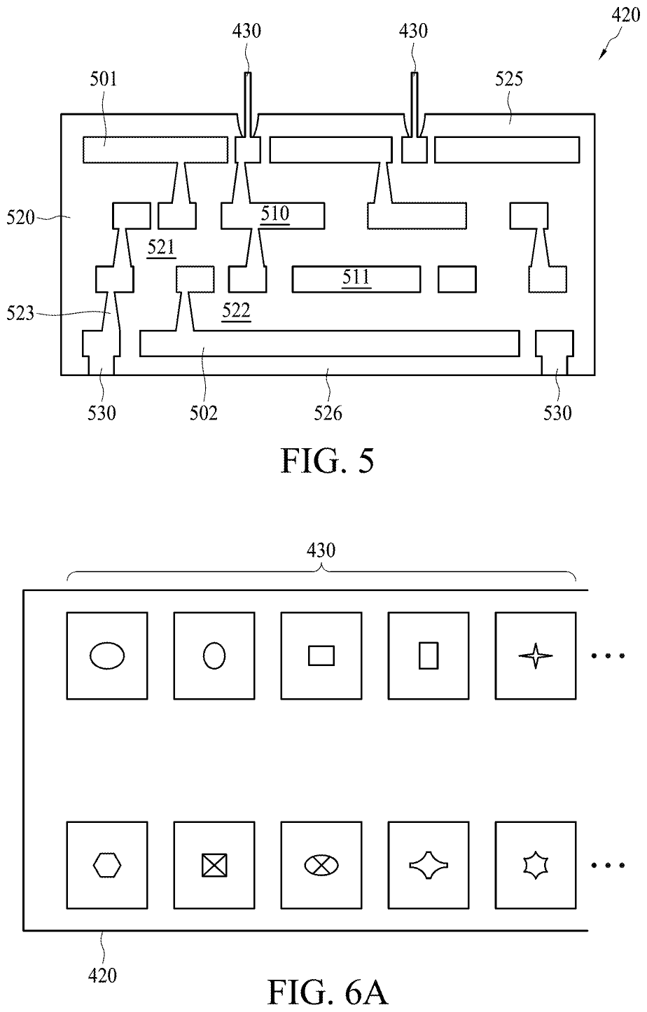

FIG. 5 is a side cross-sectional view of the flexible interconnect substrate 120 according to some embodiments of the present disclosure. With reference to FIG. 5, the flexible interconnect substrate 420 includes a plurality of ground layers 501 and 502, a plurality of signal layers 510 and 511, a plurality of dielectric layers 520, 521, and 522, a plurality of vias 523, a plurality of passivation layers 525 and 526, and metal pads 530. In some embodiments, the flexible interconnect substrate 420 may be a multi-layer membrane-like substrate. As shown in the illustrative example of FIG. 5, the flexible interconnect substrate 420 may include a plurality of metal layers with polymer dielectric layers in between. In the flexible interconnect substrate 420 of FIG. 5, the ground layers 501 and 502 form the external layers which may be in a form of solid metal plane or mesh-net like metal networks. The signal layers 510 and 511 are metal layers formed in between the ground layers 501 and 502. The metal vias 523 interconnect the signal layers 510 and 511 by vertically penetrating through the polymer dielectric layers 520, 521, and 522. In some embodiments, probe 430 may be fabricated on the ground layer 501 by a micro-electro-mechanical system (MEMS) process, an electrolytic plating process, a thin film process, or other suitable processing methods. The probe 430 may be fabricated on the ground layer 501 at predetermined locations (or coordinates) which are mirror image counterparts of the centers of the pads 151 on the device 150 to be tested (e.g. integrated circuit chip). In some embodiments, the metal pads 530 and/or metal bumps may be optionally erected on the ground layer 502 at predetermined solder joint spots by a standard soldering process, so as to enhance a reliable connection to the circuit board 410. The metal bump structure may form the electrical connections 421 and may also be erected by an electrolytic plating process.

In some embodiments, a thickness of the metal layers of the flexible interconnect substrate 420 may range from 1 μm to more than 20 μm, 3 μm to 10 μm, or 3 μm to 8 μm depending on the particular applications of the probing apparatus 100. A surface roughness of the metal layers may range from below 1 Å to 200 Å, below 1 Å to 100 Å, or 1 Å to 25 Å depending on the particular applications. In some embodiments, a line width/gap of the flexible interconnect substrate 420 has a range of 2 μm to 150 μm, 5 μm to 75 μm, 5 μm to 50 μm, or 5 μm to 35 μm depending on the particular applications of the probing apparatus 400. In some embodiments, the flexible interconnect substrate 420 may be fabricated by a thin film build-up process, a fine pitch printed circuit board (PCB) process, a combination of thin film and fine pitch PCB process, or a fine pitch flexible circuit board process.

In some embodiments, passive components, such as resistors, capacitors, or inductors may be integrated into the traces of the signal layers 510 and 511 of the flexible interconnect substrate 420 by a thin film process to perform specially designed functions such as electrical noise filtering, signal pull-up or pull-down, or other functions according to embodiments of the present disclosure. This thin film passive device integration further enables a high-density interconnect (HDI) flexible substrate of electrical routing layouts capable of performing specialized functions.

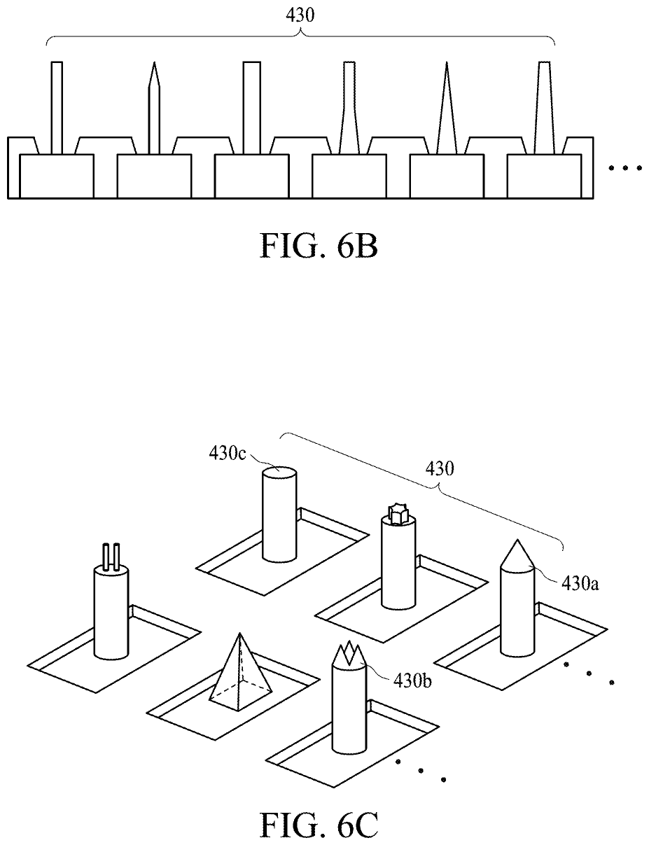

FIG. 6A is a top view of the probe 430, FIG. 6B is a side cross-sectional view of the probe 430, and FIG. 6C is a perspective view of the probe 430 according to some embodiments of the present disclosure. With reference to FIG. 5 and FIG. 6A to FIG. 6C, in some embodiments, the probe 430 is presented in a form of a metal post. The probe 430 may be formed to have a simple or complex geometrical shape, a symmetrical or asymmetrical cross-section as shown in FIG. 6A and FIG. 6B, and to have a single contact mark 430a, a plurality of contact marks 430b, or a contact mark area 430c, as shown in FIG. 6C. As seen in the illustrative example of FIG. 6A, the top-view shape of the probe 430 may vary from a circle, an oval, or to other symmetrical shapes or other irregular shapes. As seen in the illustrative example of FIG. 6B, the cross-section of the probe 430 may be rectangular, trapezoidal, square, triangular, or other symmetrical or asymmetrical cross-sections. It should be noted that, the probes 430 presented in FIG. 6A to FIG. 6C serve merely as illustrative examples of the shapes, cross-sections, and contact marks the probe 430 may have. The probe apparatus 400 may have probes 430 of different shapes, cross-sections, and contact marks compared to those presented in FIG. 6A to FIG. 6C. In another example, the probes 430 may have uniform shapes, cross-sections, and contact marks, or a mixture thereof according to some embodiments of the present disclosure. In some embodiments, a diameter of the probe 430 may vary from 1 μm to more than 30 μm, 1 μm to 10 μm, or 2 μm to 8 μm depending on the particular applications of the probing apparatus 400. In some embodiments, an inter-probe pitch may range from less than 30 μm to more than 100 μm, 35 μm to 75 μm, or 40 μm to 60 μm depending on the particular applications of the probing apparatus 400.

In some embodiments, the probes 430 of the probe apparatus 400 may be MEMS probes precisely positioned and uniformly made by a thin film process to have a pitch of 50 μm or less and compatible with semiconductor integrated circuit (IC) chips. If needed by particular applications, the probes 430 may be enhanced by plating or thermal tempering or other alternative methods, so as to easily surpass one million touch-downs under standard IC testing operation at room and elevated temperatures as well as under cycling of current or voltage, or functional testing in air or other types of atmospheres. A probe pitch of the probe 430 may be defined by a thin film process to match the needs of particular applications over a wide range of dimensions. For instance, the probe pitch may be as large as 1000 μm for semiconductor package or substrate testing, or smaller than 50 μm for fine pitch IC silicon wafer or wafer scale package testing. In some embodiments, a physical height of the probe 430 may range from less than 10 μm to more than 100 μm, depending on the particular applications of the probe apparatus 400.

In some embodiments, the probe 430 may be made of a simple and/or complex conductive material system with acceptable robustness and surface toughness. High conductivity metals and metal alloys may be used to manufacture the probe 430. In some embodiments, the probe 430 may be made of a single metal system, such as copper (Cu), silver (Ag), other suitable metallic equivalents, or an alloy system, such as bronze or Paliney 6 alloy or the like. In some embodiments, a grinding resistance of the probe 430 may be further improved by coating the probe 430 with a hard film, such as a nickel (Ni) film or the like. Other conductive material systems may be used for the probe 430, such as highly conductive oxides, polymers, composites, or other unforeseen disruptive conductive materials to be developed in future. In some embodiments, the probe 430 may be custom-made to meet demanding requirements of particular applications, such as corrosion resistance, abrasion resistance, chemical inertness, or other unique requirements. In some embodiments, the width or the diameter of the probe 430 may be made to gradually expand along a longitudinal axis of the probe 430, from the tip to the base of the probe 430, in order to enhance the position anchoring of the probe 430. In some embodiments, the probe 430 may be fabricated by a thin film MEMS process, a thin film deposition method, an electrolytic plating (or bumping) method, a stud bonding assembly method, or by a combination of any two or more of the aforementioned methods or new processing techniques yet to be invented.

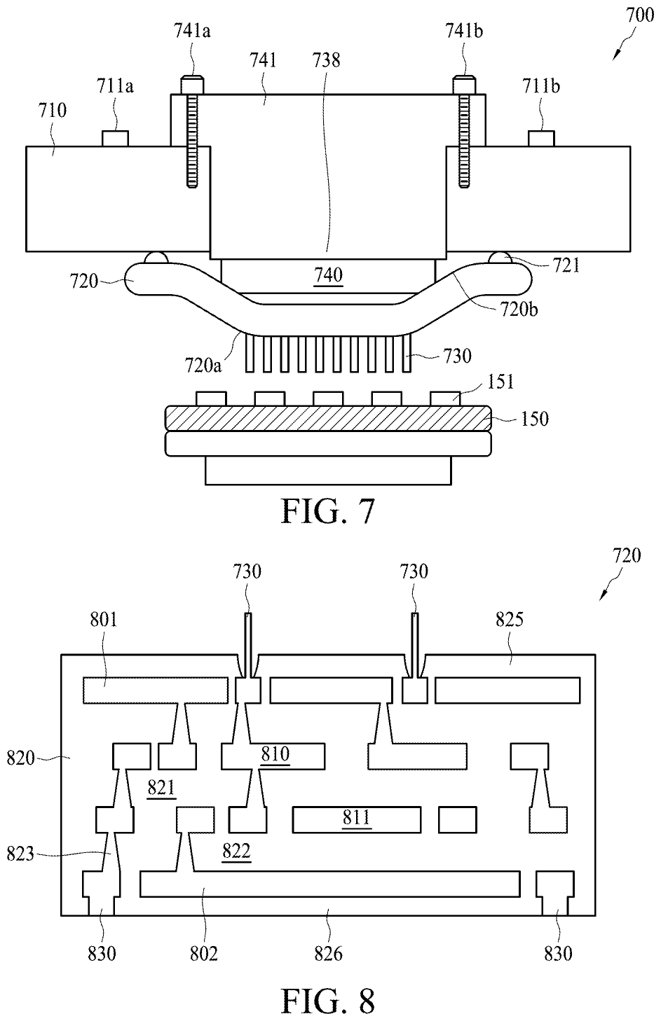

It should be noted that, in some embodiments of the present disclosure, the supporting element of the probe apparatus may be configured differently than in the probe apparatuses 100 and 400. FIG. 7 is a schematic diagram of a probe apparatus 700 according to some embodiments of the present disclosure. With reference to FIG. 7, the probe apparatus 700 includes a circuit board 710, a flexible interconnect substrate 720, at least one probe 730, and a supporting element 740. Compared to the probe apparatus 100 of FIG. 1 and the probe apparatus 400 of FIG. 4, the supporting element 740 is mechanically supported by a metal block 741 attached to the circuit board 710 by the fasteners 741a and 741b. In some embodiments, the circuit board 710 includes contact pads 711a and 711b for making contact with a tester equipment (not shown), for example. The contact pads 711a and 711b may make contact with pogo-style pins of the tester equipment, for instance. The circuit board 710 may also serve as a carrier board for the flexible interconnect substrate 720. In some embodiments, the flexible interconnect substrate 720 has a first surface 720a and an opposing second surface 720b, and the flexible interconnect substrate 720 is electrically coupled to the circuit board 710 through the electrical connections 721.

In some embodiments, the electrical connections 721 serve to electrically and mechanically connect the circuit board 710 to the flexible interconnect substrate 720. The electrical connections 721 may include metal bumps formed with copper (Cu), gold (Au), silver (Ag), nickel (Ni), solder (Pb/Sn), bronze, brass, Paliney 6 alloy, or other suitable materials according to an electrolytic plating method, a reflow solder method, a direct inter-metal bonding method, a deposition method, or other suitable methods. In some embodiments, the electrical connections 721 may include stud bumps that are formed with gold (Au) or other suitable materials according to a wire bonding method. However, the electrical connections 721 are not limited to these types of structures. In some embodiments, when it is possible to obtain a desired electric connection by another method, the electrical connections 721 need not exist. In some embodiments, connection mediums other than metal bumps or stud bumps may be provided.

In some embodiments, the probe 730 is disposed in the first surface 720a of the flexible interconnect substrate 720. The probe 730 is electrically coupled to the flexible interconnect substrate 720, and the probe 730 is configured to electrically contact pads 151 of a device 150 under test. In some embodiments, the supporting element 740 is adhered to a region 738 of the metal block 741 facing the second surface 720b of the flexible interconnect substrate 720, by using an epoxy resin based adhering agent or other suitable adhesives, for example. The metal block 741 is attached to the circuit board 710 by the fasteners 741a and 741b, and the supporting element 740 is disposed between the flexible interconnect substrate 720 and the circuit board 710. In some embodiments, the metal block 741 may be made of stainless steel, toughened aluminum, anodized metals, toughened alloys, or other suitable alternatives. It should be noted that, the metal block 741 may also be replaced by polymeric materials, such as polymeric composites or other suitable alternatives. It should be further noted that, in some embodiments, the supporting element 740 may also be adhered to both the metal block 741 and the flexible interconnect substrate 720 by an epoxy resin based adhering agent or other suitable adhesives, for example.

In some embodiments, the supporting element 740 may be an anisotropic elastomer that may serve as a mechanical cushion to enhance the uniformity of a contact force of the probe 730 across the whole device 150 under test. The anisotropic elastomer material of the supporting element 740 may be made to have a homogeneous texture or a non-homogeneous texture, and/or homogeneous or non-homogeneous ingredients. In some embodiments, the anisotropic elastomer material of the supporting element 740 may be made to have a heterogeneous texture and/or heterogeneous ingredients. Accordingly, this may enable the supporting element 740 to be more dexterous while probing the device 150 under test, thereby minimizing or eliminating a potential contact damage to the device 150 under test. A thickness of the supporting element 740 may range from 0.1 mm to 15 mm, although the thickness of the supporting element 740 may be 0.3 mm to 1 mm, 0.4 mm to 1 mm, or 0.4 mm to 0.6 mm depending on particular applications of the probe apparatus 700 according to some embodiments of the present disclosure.

FIG. 8 is a side cross-sectional view of the flexible interconnect substrate 720 according to some embodiments of the present disclosure. With reference to FIG. 8, the flexible interconnect substrate 720 includes a plurality of ground layers 801 and 802, a plurality of signal layers 810 and 811, a plurality of dielectric layers 820, 821, and 822, a plurality of vias 823, a plurality of passivation layers 825 and 826, and metal pads 830. In some embodiments, the flexible interconnect substrate 720 may be a multi-layer membrane-like substrate. As shown in the illustrative example of FIG. 8, the flexible interconnect substrate 720 may include a plurality of metal layers with polymer dielectric layers in between. In the flexible interconnect substrate 720 of FIG. 8, the ground layers 801 and 802 form the external layers which may be in a form of solid metal plane or mesh-net like metal networks. The signal layers 810 and 811 are metal layers formed in between the ground layers 801 and 802. The metal vias 823 interconnect the signal layers 810 and 811 by vertically penetrating through the polymer dielectric layers 820, 821, and 822. In some embodiments, the probe 730 may be fabricated on the ground layer 801 by a micro-electro-mechanical system (MEMS) process, an electrolytic plating process, a thin film process, or other suitable processing methods. The probe 730 may be fabricated on the ground layer 801 at predetermined locations (or coordinates) which are mirror image counterparts of the centers of the pads 151 on the device 150 to be tested (e.g. integrated circuit chip). In some embodiments, the metal pads 830 and/or metal bumps may be optionally erected on the ground layer 802 at predetermined solder joint spots by a standard soldering process, so as to enhance a reliable connection to the circuit board 710. The metal bump structure may form the electrical connections 721 and may also be erected by an electrolytic plating process.

In some embodiments, a thickness of the metal layers of the flexible interconnect substrate 720 may range from 1 μm to more than 20 μm, 3 μm to 10 μm, or 3 μm to 8 μm depending on the particular applications of the probing apparatus 700. A surface roughness of the metal layers may range from below 1 Å to 200 Å, below 1 Å to 100 Å, or 1 Å to 25 Å depending on the particular applications. In some embodiments, a line width/gap of the flexible interconnect substrate 720 has a range of 2 μm to 150 μm, 5 μm to 75 μm, 5 μm to 50 μm, or 5 μm to 35 μm depending on the particular applications of the probing apparatus 700. In some embodiments, the flexible interconnect substrate 720 may be fabricated by a thin film build-up process, a fine pitch printed circuit board (PCB) process, a combination of thin film and fine pitch PCB process, or a fine pitch flexible circuit board process.

In some embodiments, passive components, such as resistors, capacitors, or inductors may be integrated into the traces of the signal layers 810 and 811 of the flexible interconnect substrate 720 by a thin film process to perform specially designed functions such as electrical noise filtering, signal pull-up or pull-down, or other functions according to embodiments of the present disclosure. This thin film passive device integration further enables a high-density interconnect (HDI) flexible substrate of electrical routing layouts capable of performing specialized functions.

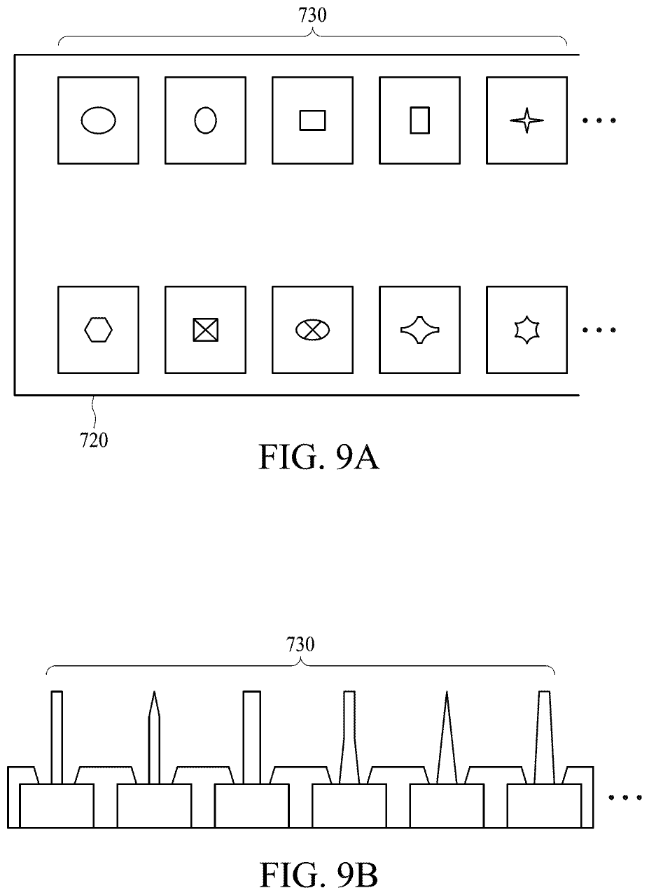

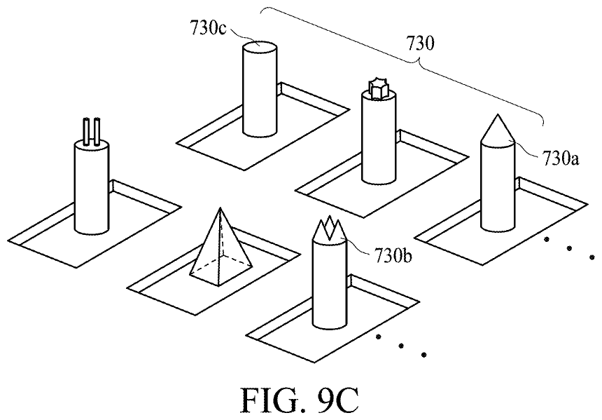

FIG. 9A is a top view of the probe 730, FIG. 9B is a side cross-sectional view of the probe 730, and FIG. 9C is a perspective view of the probe 730 according to some embodiments of the present disclosure. With reference to FIG. 8 and FIG. 9A to FIG. 9C, in some embodiments, the probe 730 is presented in a form of a metal post. The probe 730 may be formed to have a simple or complex geometrical shape, a symmetrical or asymmetrical cross-section as shown in FIG. 9A and FIG. 9B, and to have a single contact mark 730a, a plurality of contact marks 730b, or a contact mark area 730c, as shown in FIG. 9C. As seen in the illustrative example of FIG. 9A, the top-view shape of the probe 730 may vary from a circle, an oval, or to other symmetrical shapes or other irregular shapes. As seen in the illustrative example of FIG. 9B, the cross-section of the probe 730 may be rectangular, trapezoidal, square, triangular, or other symmetrical or asymmetrical cross-sections. It should be noted that, the probes 730 presented in FIG. 9A to FIG. 9C serve merely as illustrative examples of the shapes, cross-sections, and contact marks the probe 730 may have. The probe apparatus 700 may have probes 730 of different shapes, cross-sections, and contact marks compared to those presented in FIG. 9A to FIG. 9C. In another example, the probes 730 may have uniform shapes, cross-sections, and contact marks, or a mixture thereof according to some embodiments of the present disclosure. In some embodiments, a diameter of the probe 730 may vary from 1 μm to more than 30 μm, 1 μm to 10 μm, or 2 μm to 8 μm depending on the particular applications of the probing apparatus 700. In some embodiments, an inter-probe pitch may range from less than 30 μm to more than 100 μm, 35 μm to 75 μm, or 40 μm to 60 μm depending on the particular applications of the probing apparatus 700.

In some embodiments, the probes 730 of the probe apparatus 700 may be MEMS probes precisely positioned and uniformly made by a thin film process to have a pitch of 50 μm or less and compatible with semiconductor integrated circuit (IC) chips. If needed by particular applications, the probes 730 may be enhanced by plating or thermal tempering or other alternative methods, so as to easily surpass one million touch-downs under standard IC testing operation at room and elevated temperatures as well as under cycling of current or voltage, or functional testing in air or other types of atmospheres. A probe pitch of the probe 730 may be defined by a thin film process to match the needs of particular applications over a wide range of dimensions. For instance, the probe pitch may be as large as 1000 μm for semiconductor package or substrate testing, or smaller than 50 μm for fine pitch IC silicon wafer or wafer scale package testing. In some embodiments, a physical height of the probe 730 may range from less than 10 μm to more than 100 μm, depending on the particular applications of the probe apparatus 700.

In some embodiments, the probe 730 may be made of a simple and/or complex conductive material system with acceptable robustness and surface toughness. High conductivity metals and metal alloys may be used to manufacture the probe 730. In some embodiments, the probe 730 may be made of a single metal system, such as copper (Cu), silver (Ag), other suitable metallic equivalents, or an alloy system, such as bronze or Paliney 6 alloy or the like. In some embodiments, a grinding resistance of the probe 730 may be further improved by coating the probe 730 with a hard film, such as a nickel (Ni) film or the like. Other conductive material systems may be used for the probe 730, such as highly conductive oxides, polymers, composites, or other unforeseen disruptive conductive materials to be developed in future. In some embodiments, the probe 730 may be custom-made to meet demanding requirements of particular applications, such as corrosion resistance, abrasion resistance, chemical inertness, or other unique requirements. In some embodiments, the width or the diameter of the probe 730 may be made to gradually expand along a longitudinal axis of the probe 730, from the tip to the base of the probe 730, in order to enhance the position anchoring of the probe 130. In some embodiments, the probe 730 may be fabricated by a thin film MEMS process, a thin film deposition method, an electrolytic plating (or bumping) method, a stud bonding assembly method, or by a combination of any two or more of the aforementioned methods or yet to be invented new processing techniques.

Accordingly, due to the supporting elements in the probe apparatuses of the present disclosure, potential contact damage with the device under test can be minimized or eliminated. Moreover, the supporting elements serve as mechanical cushions to enhance the uniformity of the contact force of the probes across the whole device under test. On the other hand, device integration in the flexible interconnect substrates of the probe apparatuses enable high density interconnect (HDI) electrical routing layouts capable of performing specialized functions.

One aspect of the present disclosure provides a probe apparatus, including a circuit board, a flexible interconnect substrate, at least one probe, and a supporting element. The circuit board includes tester contacts. The flexible interconnect substrate has a first surface and an opposing second surface, wherein the flexible interconnect substrate is electrically coupled to the circuit board. The probe is disposed in the first surface of the flexible interconnect substrate, wherein the probe is electrically coupled to the flexible interconnect substrate, and the probe is configured to electrically contact a device under test. The supporting element is adhered to the second surface of the flexible interconnect substrate, wherein the supporting element is disposed between the flexible interconnect substrate and the circuit board.

Another aspect of the present disclosure provides a probe apparatus, including a circuit board, a flexible interconnect substrate, at least one probe, and a supporting element. The circuit board includes tester contacts. The flexible interconnect substrate has a first surface and an opposing second surface, wherein the flexible interconnect substrate is electrically coupled to the circuit board. The probe is disposed in the first surface of the flexible interconnect substrate, wherein the probe is electrically coupled to the flexible interconnect substrate, and the probe is configured to electrically contact a device under test. The supporting element is adhered to a region of the circuit board facing the second surface of the flexible interconnect substrate, wherein the supporting element is disposed between the flexible interconnect substrate and the circuit board.

Another aspect of the present disclosure provides a probe apparatus, including a circuit board, a flexible interconnect substrate, at least one probe, and a supporting element. The circuit board includes tester contacts. The flexible interconnect substrate has a first surface and an opposing second surface, wherein the flexible interconnect substrate is electrically coupled to the circuit board. The probe is disposed in the first surface of the flexible interconnect substrate, wherein the probe is electrically coupled to the flexible interconnect substrate, and the probe is configured to electrically contact a device under test. The supporting element is adhered to a region of a metal block facing the second surface of the flexible interconnect substrate, wherein the metal block is attached to the circuit board, and the supporting element is disposed between the flexible interconnect substrate and the circuit board.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, and steps.

What is claimed is:

1. A probe apparatus, comprising:
a circuit board comprising tester contacts;
a flexible interconnect substrate having a first surface and an opposing second surface, wherein the flexible interconnect substrate is electrically coupled to the circuit board;
at least one probe disposed in the first surface of the flexible interconnect substrate, wherein the probe is electrically coupled to the flexible interconnect substrate, and the probe is configured to electrically contact a device under test; and
a supporting element adhered to the second surface of the flexible interconnect substrate, wherein the supporting element is disposed between the flexible interconnect substrate and the circuit board.

2. The probe apparatus of claim 1, wherein the supporting element is an anisotropic elastomer comprising a homogeneous or non-homogeneous texture.

3. The probe apparatus of claim 1, wherein the supporting element is an anisotropic elastomer comprising a heterogeneous texture.

4. The probe apparatus of claim 1, wherein the probe comprises a symmetrical cross-section.

5. The probe apparatus of claim 1, wherein the probe comprises an asymmetrical cross-section.

6. The probe apparatus of claim 1, wherein the probe comprises a single contact mark, a plurality of contact marks, or a contact mark area.

7. The probe apparatus of claim 1, wherein the flexible interconnect substrate comprises a plurality of ground layers, a plurality of signal layers, and a plurality of dielectric layers.

8. A probe apparatus, comprising:
a circuit board comprising tester contacts;
a flexible interconnect substrate having a first surface and an opposing second surface, wherein the flexible interconnect substrate is electrically coupled to the circuit board;
at least one probe disposed in the first surface of the flexible interconnect substrate, wherein the probe is electrically coupled to the flexible interconnect substrate, and the probe is configured to electrically contact a device under test; and
a supporting element adhered to a region of the circuit board facing the second surface of the flexible interconnect substrate, wherein the supporting element is disposed between the flexible interconnect substrate and the circuit board.

9. The probe apparatus of claim 8, comprising:
wherein a metal film is disposed between the supporting element and the circuit board.

10. The probe apparatus of claim 8, wherein the supporting element is an anisotropic elastomer comprising a homogeneous texture, a non-homogeneous texture, or a heterogeneous texture.

11. The probe apparatus of claim 8, wherein the probe comprises a symmetrical cross-section.

12. The probe apparatus of claim 8, wherein the probe comprises an asymmetrical cross-section.

13. The probe apparatus of claim 8, wherein the probe comprises a single contact mark, a plurality of contact marks, or a contact mark area.

14. The probe apparatus of claim 8, wherein the flexible interconnect substrate comprises a plurality of ground layers, a plurality of signal layers, and a plurality of dielectric layers.

15. A probe apparatus, comprising:
a circuit board comprising tester contacts;
a flexible interconnect substrate having a first surface and an opposing second surface, wherein the flexible interconnect substrate is electrically coupled to the circuit board;
at least one probe disposed in the first surface of the flexible interconnect substrate, wherein the probe is electrically coupled to the flexible interconnect substrate, and the probe is configured to electrically contact a device under test; and
a supporting element adhered to a region of a metal block facing the second surface of the flexible interconnect substrate, wherein the metal block is attached to the circuit board, and the supporting element is disposed between the flexible interconnect substrate and the circuit board.

16. The probe apparatus of claim 15, wherein the supporting element is an anisotropic elastomer comprising a homogeneous texture, a non-homogeneous texture or a heterogeneous texture.

17. The probe apparatus of claim 15, wherein the probe comprises a symmetrical cross-section.

18. The probe apparatus of claim 15, wherein the probe comprises an asymmetrical cross-section.

19. The probe apparatus of claim 15, wherein the probe comprises a single contact mark, a plurality of contact marks, or a contact mark area.

20. The probe apparatus of claim 15, wherein the flexible interconnect substrate comprises a plurality of ground layers, a plurality of signal layers, and a plurality of dielectric layers.
